(19) United States
(12) Patent Application Publication
(10) Pub. No.: US 2013/0126344 A1
(43) Pub. Date: May 23, 2013

(54) IGZO NANOPARTICLE AND MANUFACTURING METHOD AND USE THEREOF

(71) Applicants: Lik-Hang CHAU, Tainan City (TW); Yu-Hsien CHOU, Tainan City (TW); Chih-Chao YANG, Tainan City (TW)

(72) Inventors: Lik-Hang CHAU, Tainan City (TW); Yu-Hsien CHOU, Tainan City (TW); Chih-Chao YANG, Tainan City (TW)

(21) Appl. No.: 13/411,215

(22) Filed: Mar. 2, 2012

(30) Foreign Application Priority Data
Nov. 23, 2011 (TW) 100142884

(51) Int. Cl. C23C 14/34; C09D 1/00; B82Y 30/00; B82Y 40/00

(52) U.S. Cl. 204/298.13; 106/286.2; 977/773; 977/840; 977/902

(57) ABSTRACT

The present disclosure provides an IGZO nanoparticle, including an InGaZnO₄ crystal structure and a trace element, wherein the InGaZnO₄ crystal structure has a formula represented by formula: x(In₂O₃)−y(Ga₂O₃)−z(ZnO), wherein x:y:z=1:1:0.5-2, and the trace element includes boron and/or aluminum, which is present in an amount of about 100-1000 ppm. The present disclosure also provides a manufacturing method for the IGZO nanoparticle and a sputter target containing the IGZO particles.

### CROSS REFERENCE TO RELATED APPLICATIONS

This application claims priority of Taiwan Patent Application No. 100142884, filed on Nov. 23, 2011, the entirety of which is incorporated by reference herein.

### BACKGROUND OF THE DISCLOSURE

1. Field of the Disclosure

The present disclosure relates to an indium gallium zinc oxide (IGZO) nanoparticle, a manufacturing method thereof and a sputter target produced by the indium gallium zinc oxide (IGZO) nanoparticle.

2. Description of the Related Art

a-IGZO has emerged as a promising candidate for replacing conventional a-Si or poly-Si thin-film transistors (TFT). a-IGZO has better electrical properties than a-Si mainly due to the following: (1) In³⁺ provides high electron mobility; (2) Zn²⁺ provides amorphous structural stability; and (3) Ga³⁺ provides high electron density. This material is suitable for the existing flat panel display (FPD) manufacturing process as well as for large substrate sizes. The electron mobility of a-IGZO (approximately 10 cm²/Vs, and the threshold voltage drift is almost uniform) and its reliability are higher than those of traditional hydrogenated amorphous silicon thin-film transistors (<1 cm²/Vs), and a-IGZO is characterized by, having a stable amorphous structure, a high electron density, and better uniformity than the low-temperature-polysilicon, and being able to be manufactured at room temperature. Therefore, a-IGZO thin film transistors are promising candidates for replacing the hydrogenated amorphous silicon thin-film transistors and the low-temperature-polysilicon thin film transistors in active matrix organic light emitting displays (AMOLED).

In the thin-film transistor (TFT) industry, an RF/DC sputtering system is commonly used to produce an a-IGZO film, because the sputtering method has advantages of good quality, low cost, large-scale production, and low pollutants.

The quality of the IGZO sputter target affects the electrical and physical properties of the IGZO thin film formed by the RF/DC sputtering system. Besides the deposition parameters, the quality of the sputtered film can be affected by the relative density, conductivity, grain size, microstructure, and purity of the sputter target. The quality of transparent conductive films, such as Ga-doped ZnO (GZO), is directly affected by the density of the sputter target. With a low density, voids on the surface of the sputter target easily lead to the formation of nodules. Therefore the electric field on the surface of a sputter target is non-uniform, and a strong electrical field can be formed extremely easily, causing a locally high impact energy such that oxygen is easily ionized by Ar or other gaseous ions to form a high resistance area. Furthermore, some particles may migrate from the nodules to films during the coating process, reducing film quality.

Currently, commercial IGZO sputter targets are mainly produced by a physical method, solid state reaction. Such method includes: directly grinding three kinds of powders, In₂O₃, ZnO, and Ga₂O₃ (average particle size in micro level) followed by pelletizing, compression molding, and high-temperature sintering (1200-1500° C.) to produce a sputter target. Although the process for the solid state reaction is simple, the uniformity of mechanical mixing has its limitation. When the distribution of doped metal oxides is non-uniform during the ball milling, or the specific surface area of the ground metal oxides is too small, the ZnGa₂O₄ spinel phase easily precipitates out, increasing nodules in the sputter target, which in turn affects the stability of the coating process and the quality of the IGZO films produced by RF/DC sputtering. In addition, the mixed particles generally have a large size (0.6-1.0 μm) causing non-uniformity during compression molding, and the density of the sputter target is reduced as a result. While the IGZO sputter targets can be mass-produced by solid state reaction, the Ga doping may be non-uniform by directly grinding the In₂O₃, ZnO, and Ga₂O₃ powder, wherein Ga or In is doped into ZnO crystalline to replace Zn atoms to control or reduce the resistance. The uniformity of the distribution of each element in the IGZO is crucial to reduce the resistance in order to control the quality of IGZO films formed by RF/DC sputtering.

Accordingly, what is needed in the art is a method for manufacturing a sputter target, wherein the problems with conventional solid state reactions such as non-uniform distribution of elements and doping can be overcome. In the present method, nanoparticles are employed to reduce the sintering temperature of the sputter target, to provide advantages in energy saving.

### BRIEF SUMMARY OF THE DISCLOSURE

The present disclosure provides an IGZO nanoparticle, including: an InGaZnO₄ crystal structure and a trace element, wherein the InGaZnO4 crystal structure has a formula represented by formula I:

x(In₂O₃)−y(Ga₂O₃)−z(ZnO) (I),

wherein x:y:z=1:1:0.5-2, and the trace element includes boron and/or aluminum, which is present in an amount of about 100-1000 ppm.

The present disclosure also provides a sputter target prepared by compression molding and sintering the indium gallium zinc oxide (IGZO) nanoparticle.

The present disclosure also provides a manufacturing method for an indium gallium zinc oxide (IGZO) nanoparticle, comprising: dissolving an indium compound, a gallium compound, and a zinc compound in a solvent, wherein the indium compound, the gallium compound, and the zinc compound have an indium:gallium:zinc molar ratio of 2:2:1-1:1:1; adding a trace element and a precipitant to produce a precipitate, wherein the trace element includes boron and/or aluminum, which is present in an amount of about 100-1000 ppm; and sintering the precipitate at a temperature of 700-1400° C. to form an indium gallium zinc oxide (IGZO) nanoparticle.

Hereinafter, embodiments of the present disclosure will be explained in detail with reference to the accompanying drawings.

### BRIEF DESCRIPTION OF THE DRAWINGS

FIG. 1 illustrates an X-ray diffraction image of the indium gallium zinc oxide (IGZO) nanoparticle according to the embodiment of the present disclosure.

FIG. 2 illustrates an electron microscope image of the indium gallium zinc oxide (IGZO) nanoparticle according to the embodiment of the present disclosure

### DETAILED DESCRIPTION OF THE DISCLOSURE

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

According to the present disclosure, three kinds of salts serving as the starting materials are dissolved in a solvent to prepare a homogeneous solution, and then, after a suitable precipitant is added to form precipitated precursors, such as complex salts, hydroxides, solid solutions, and composite oxides in the solution. The obtained precipitated precursors are washed with water, filtrated, dried, and subjected to thermal decomposition or dehydration to form the desirable crystalline IGZO nanoparticle.

According to the embodiments in the present disclosure, the manufacturing method for an indium gallium zinc oxide (IGZO) nanoparticle, comprise: dissolving an indium compound, a gallium compound, and a zinc compound in a solvent, wherein the indium compound, the gallium compound, and the zinc compound have an indium:gallium:zinc molar ratio of 2:2:1-1:1:1, preferably 1:1:1. The indium compound includes but is not limited to: indium nitrate, indium sulfate, indium sulfite, indium phosphate, indium hypophosphite, or combinations thereof. The gallium metal compound includes but is not limited to: gallium nitrate, gallium sulfate, gallium sulfite, gallium phosphate, gallium hypophosphite, or combinations thereof. The zinc compound comprises: zinc nitrate, zinc sulfate, zinc sulfite, zinc phosphate, zinc hypophophite, or combinations thereof. A trace element and a precipitant are added to produce a precipitate. The trace element includes boron and/or aluminum, which is present in an amount of about 100-1000 ppm, preferably about 200-800 ppm, and more preferably about 300-500 ppm. The precipitant includes but is not limited to: ammonia, sodium hydroxide, potassium hydroxide, or combinations thereof, wherein the molar ratio of the precipitant/zinc is about 3-8, preferably about 5. Further, the precipitate is washed, separated, and sintered at a temperature of 700-1400° C., preferably 800-1200° C., for about 3-8 hours, preferably about 5 hours, to form an indium gallium zinc oxide (IGZO) nanoparticle. The indium gallium zinc oxide (IGZO) nanoparticle has a purity of more than about 99%, preferably more than about 99.5%

Compared to the traditional solid state reaction, there are fewer amounts of impurities by using coprecipitation, and therefore the powder is obtained with higher chemical uniformity. The main characters of coprecipitation are low costs, simple processes, and ability for mass production. The compositional difference between the traditional IGZO and the IGZO prepared by the present method is the presence of the trace elements, such as boron and/or aluminum, which are added in the present method to refine the grain size of the sputter target and inhibit the formation of the heterogeneous phase.

According to the embodiments in the present disclosure, the indium gallium zinc oxide (IGZO) nanoparticle produced by the present method, include: an InGaZnO₄ crystal structure and a trace element, wherein the InGaZnO₄ crystal structure has a formula represented by formula I:

x(In₂O₃)−y(Ga₂O₃)−z(ZnO) (I),

wherein x:y:z=1:1:0.5-2, and the trace element includes boron and/or aluminum, which is present in an amount of about 100-1000 ppm, preferably about 200-800 ppm, more preferably about 300-500 ppm. In an embodiment, the indium gallium zinc oxide (IGZO) nanoparticle has a purity of more than about 99%, preferably more than about 99.5%. According to the embodiments in the present disclosure, the indium gallium zinc oxide (IGZO) nanoparticle is a single phase of a InGaZnO₄ crystal structure and free of a ZnGa₂O₄ spinel phase. The IGZO nanoparticle has an average particle size of smaller than about 100 nm, preferably smaller than about 80 nm, more preferably smaller than about 50 nm, and a l/d aspect ratio of about 1-2, wherein the l/d aspect ratio is the ratio of the diameter (d) and the length (l) in a single particle.

To produce a sputter target, the indium gallium zinc oxide (IGZO) nanoparticle according to the present disclosure is mixed with polyvinyl acetate (PVA, commercial product), and deionized water to form an aqueous solution, wherein the PVA is present in an amount of about 0.1-0.3 wt %, preferably 0.15-0.25 wt %, and the indium gallium zinc oxide (IGZO) nanoparticle is present in an amount of about 10-25 wt % (100 ml of aqueous solution), preferably about 15-20 wt % (100 ml of aqueous solution). The mixed IGZO aqueous solution is first subjected to spray granulation to produce spherical IGZO particles with a particle size of larger than about 5-20 μm, and then the spherical IGZO particles is compression molded by a universal testing machine with a compression speed of 0.3-2 mm/min and a molding pressure of 5-30 MPa, preferably with a compression speed of 0.5-1.3 mm/min and a molding pressure of 15-26 MPa. The molded green compact is then subjected to cold isostatic pressing with a cold isostatic pressing pressure of 150-400 MPa, preferably 250-350 MPa, to form a densified green compact. Finally, the densified green compact is placed into a high-temperature sintering furnace for sintering, and the sintering condition is as follows: the temperature is increased from room temperature to 300° C. with a ramp-up speed of 0.5-3° C./min, preferably 0.8-2.5° C./min; the temperature is maintained at 300° C. to remove polyvinyl acetate (PVA) for 1-5 hours, preferably 1.5-4 hours; the temperature is increased from 300° C. to the sintering temperature of 1200-1600° C., preferably 1350-1550° C. with a ramp-up speed of 0.5-3° C./min, preferably 0.8-2° C./min, wherein the sintering temperature is maintained for 2-8 hours, preferably 4-6 hours; and the furnace is cooled naturally to obtain a sputter target.

In summary, the present disclosure provides a precursor co-precipitation method for preparing an indium gallium zinc oxide (IGZO) nanoparticle with a small particle size, homogeneous structure, high crystallinity, and high purity for application of high-quality IGZO sputter targets. The indium gallium zinc oxide (IGZO) nanoparticle according to the present disclosure is synthesized directly without a long-period of mechanical grinding, and the elements such as In, Ga, and Zn are distributed uniformly in the nanoparticle thereby improving the compactness and the uniformity of the sputter target. In addition, the sintering temperature can be lowered (700-900° C.) due to the smaller particle size of the indium gallium zinc oxide (IGZO) nanoparticle. Thus, this method is not only energy saving but also simple and fast to get a high purity product.

The features and effects of the embodiments of the disclosure are further discussed below. The specific embodiments discussed are merely illustrative, and do not limit the scope of the disclosure.

### Example 1

In the examples, the physical properties of nanoparticles were measured by the following:

### Crystal Structure of Nanoparticles

X-ray diffractometer (Philips, PW-1700)

### Particle Size of Nanoparticles

Electron microscope image analyzer (JEOL, 5400)

### Composition of Nanoparticles

X-ray energy dispersive spectrometer (JEOL, 5400)

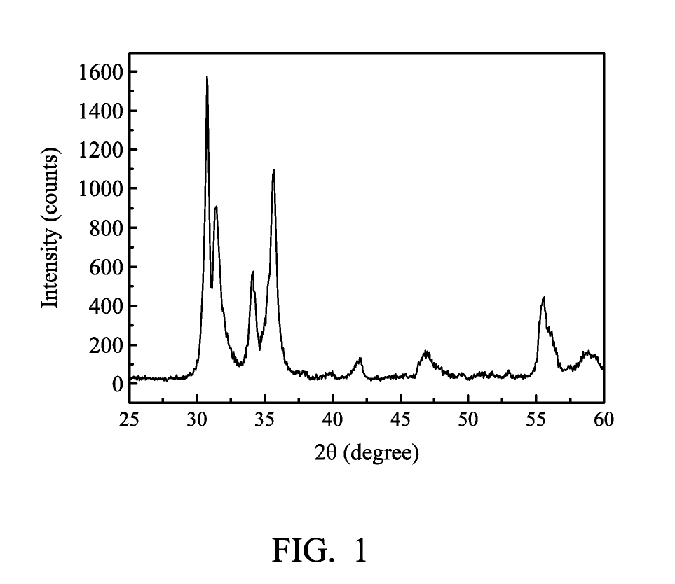

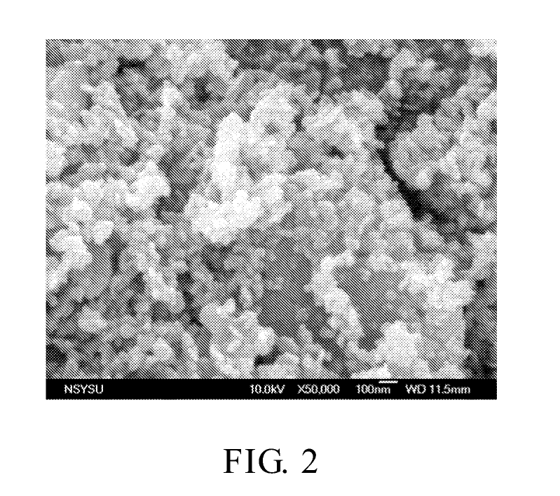

First, 22 g of indium compounds (indium nitrate), 15 g of gallium compounds (gallium nitrate), 17 g of zinc compounds (zinc nitrate), and 1 ml of trace elements (1000 μg/ml Boron in H₂O) were dissolved in 480 ml of pure water and stirred for 0.5 hours, and then 30 g of a precipitant (sodium carbonate) was added and stirred for 2 hours at room temperature to obtain a white precipitate. The white precipitate was washed with deionized water three times, separated, and dried at a temperature of 110° C. to obtain white powder. The white powder was sintered at 800° C. for 3 hours to form the indium gallium zinc oxide (IGZO) nanoparticle. FIG. 1 illustrates an X-ray diffraction image of the indium gallium zinc oxide (IGZO) nanoparticle, confirming the presence of the InGaZnO₄ crystal. FIG. 2 illustrates an electron microscope image of the indium gallium zinc oxide (IGZO) nanoparticle. The scale bar is 100 nm, and the particle size of the indium gallium zinc oxide (IGZO) nanoparticle is about 50 nm in the electron microscope image. X-ray energy dispersive spectrometer confirmed that the indium gallium zinc oxide (IGZO) is (In₂O₃)−(Ga₂O₃)−2(ZnO), and the analysis result of the composition of the indium gallium zinc oxide (IGZO) nanoparticle is shown in Table 1.

TABLE 1

| element | wt % | atomic % |
|---|---|---|
| O | 20.00 | 55.95 |
| Zn | 30.15 | 20.65 |
| Ga | 15.71 | 10.09 |
| In | 34.14 | 13.31 |
| Total | 100.00 | 100.00 |

### Example 2

The indium gallium zinc oxide (IGZO) nanoparticle of Example 1 was mixed with polyvinyl acetate (PVA, commercial product), and deionized water to form a aqueous solution, wherein the PVA was present in an amount of 0.2 wt % (100 ml of an aqueous solution), and the indium gallium zinc oxide (IGZO) nanoparticle was present in an amount of about 20 wt %. The mixed IGZO aqueous solution was first subjected to spray granulation to produce spherical IGZO particles with a particle size of about 5-12 μm, and then the spherical IGZO particles was placed into a mold with an inner diameter of 4 inches and the compression molded by a universal testing machine with a molding pressure of 25 MPa for 1 minute. The molded green compact was then subjected to cold isostatic pressing with a pressing pressure of 250 MPa to form a densified green compact.

Thereafter, the densified green compact was place into a high-temperature furnace with the following conditions: the temperature was increased from room temperature to 300° C. with a ramp-up speed of 1° C./min, the temperature was maintained at 300° C. to remove polyvinyl acetate (PVA) for 2 hours; the temperature was increased from 300° C. to the sintering temperature of 1400° C. with a ramp-up speed of 1° C./min, the sintering temperature was maintained for 5 hours; and the furnace was cooled naturally to obtain a sputter target. The surface of the sputter target was planarized by a grinding machine and wine-cut to obtain a 3-inch sputter target with a density of above 99% and a purity of above 99.9%.

### Example 3

The indium gallium zinc oxide (IGZO) nanoparticle of Example 1 was mixed with polyvinyl acetate (PVA, commercial product), and deionized water to form a aqueous solution, wherein the PVA was present in an amount of 0.2 wt % (100 ml of an aqueous solution), and the indium gallium zinc oxide (IGZO) nanoparticle was present in an amount of about 20 wt %. The mixed IGZO aqueous solution was first subjected to a spray granulation to produce spherical IGZO particles with a particle size of about 5-12 μm, and then the spherical IGZO particles was placed into a mold with an inner diameter of 4 inches and compression molded by a universal testing machine with a molding pressure of 25 MPa for 1 minute. The molded green compact was then subjected to a cold isostatic pressing with a pressing pressure of 300 MPa to form a densified green compact.

Thereafter, the densified green compact was place into a high-temperature furnace with the following conditions: the temperature was increased from room temperature to 300° C. with a ramp-up speed of 1.5° C./min, the temperature was maintained at 300° C. to remove polyvinyl acetate (PVA) for 2 hours; the temperature was increased from 300° C. to the sintering temperature of 1500° C. with a ramp-up speed of 1° C./min, the sintering temperature was maintained for 4 hours; and the furnace was cooled naturally to obtain a sputter target. The surface of the sputter target was planarized by a grinding machine and wine-cut to obtain a 3-inch sputter target with a density of above 99% and a purity of above 99.9%.

While the invention has been described in detail and with reference to specific embodiments thereof, it is to be understood that the foregoing description is exemplary and explanatory in nature and is intended to illustrate the invention and its preferred embodiments. Through routine experimentation, one skilled in the art will readily recognize that various changes and modifications can be made therein without departing from the spirit and scope of the invention. Thus, the invention is intended to be defined not by the above description, but by the following claims and their equivalents.

What is claimed is:

1. An indium gallium zinc oxide (IGZO) nanoparticle, comprising an InGaZnO₄ crystal structure and a trace element, wherein the InGaZnO₄ crystal structure has a formula represented by formula (I):
x(In₂O₃)−y(Ga₂O₃)−z(ZnO) (I),
wherein x:y:z=1:1:0.5-2, and the trace element includes boron and/or aluminum, which is present in an amount of about 100-1000 ppm.

2. The indium gallium zinc oxide (IGZO) nanoparticle according to claim 1, having a purity of more than about 99%.

3. The indium gallium zinc oxide (IGZO) nanoparticle according to claim 1, wherein the indium gallium zinc oxide (IGZO) nanoparticle is a single phase of InGaZnO₄ crystal structure.

4. The indium gallium zinc oxide (IGZO) nanoparticle according to claim 1, wherein the indium gallium zinc oxide (IGZO) nanoparticle is free of ZnGa₂O₄ spinel phase.

5. The indium gallium zinc oxide (IGZO) nanoparticle according to claim 1, wherein the indium gallium zinc oxide (IGZO) nanoparticle has an average particle size of smaller than about 100 nm and a l/d aspect ratio of about 1.

6. A sputter target, prepared by compression molding and sintering the indium gallium zinc oxide (IGZO) nanoparticle according to claim 1.

7. A manufacturing method for an indium gallium zinc oxide (IGZO) nanoparticle, comprising:
dissolving an indium compound, a gallium compound, and a zinc compound in a solvent, wherein the indium compound, the gallium compound, and the zinc compound have an indium:gallium:zinc molar ratio of 2:2:1-1:1:1;
adding a trace element and a precipitant to produce a precipitate, wherein the trace element includes boron and/or aluminum, which is present in an amount of about 100-1000 ppm; and
sintering the precipitate at a temperature of 700-1400° C. to form an indium gallium zinc oxide (IGZO) nanoparticle.

8. The manufacturing method according to claim 7, further comprising washing and separating the precipitate before sintering the same.

9. The manufacturing method according to claim 7, wherein the indium compound comprises, indium nitrate, indium sulfate, indium sulfite, indium phosphate, indium hypophosphite, or combinations thereof, the gallium metal compound comprises gallium nitrate, gallium sulfate, gallium sulfite, gallium phosphate, gallium hypophosphite, or combinations thereof, and the zinc compound comprises zinc nitrate, zinc sulfate, zinc sulfite, zinc phosphate, zinc hypophophite, or combinations thereof.

10. The manufacturing method according to claim 7, wherein the precipitant comprises ammonia, sodium hydroxide, potassium hydroxide, or combinations thereof.

11. The manufacturing method according to claim 7, wherein sintering is performed at a temperature between about 800-1200° C.

12. The manufacturing method according to claim 7, wherein the indium gallium zinc oxide (IGZO) nanoparticle has a purity of more than about 99%.

13. The manufacturing method according to claim 7, wherein the indium gallium zinc oxide (IGZO) nanoparticle is a single phase of InGaZnO₄ crystal structure.

14. The manufacturing method according to claim 7, wherein the indium gallium zinc oxide (IGZO) nanoparticle is free of ZnGa₂O₄ spinel phase.

15. The manufacturing method according to claim 7, wherein the indium gallium zinc oxide (IGZO) nanoparticle has an average particle size of smaller than 100 nm and a l/d aspect ratio of about 1.
